(19) United States
(12) Patent Application Publication
(10) Pub. No.: US 2005/0229064 A1
(43) Pub. Date: Oct. 13, 2005

(54) Methods and systems for digital testing on automatic test equipment (ATE)

(76) Inventor: David Walker Guidry, Rowlett, TX (US)

Correspondence Address: TEXAS INSTRUMENTS INCORPORATED, P O BOX 655474, M/S 3999, DALLAS, TX, 75265, US

(21) Appl. No.: 10/822,415

(22) Filed: Apr. 12, 2004

(51) Int. Cl. G01R 31/28; G06F 11/00

(52) U.S. Cl. 714/742

(57) ABSTRACT

Methods and systems for digital testing of semiconductor devices are disclosed. The inventions include testing modules (10) for use with automatic test equipment (ATE) 20 and device interface boards (32) in order to extend their capabilities to perform digital testing of semiconductor devices (18). Testing modules (10) disclosed include memory (12) and a test engine (14), which may be configured for digital testing according to further steps of the invention.

### TECHNICAL FIELD

The invention relates to testing semiconductor devices and integrated circuits (ICs). More particularly, it relates to new systems and methods for digital testing modules capable of extending the usefulness of automatic test equipment (ATE).

### BACKGROUND OF THE INVENTION

Testing can be a major contributor to the cost of semiconductor device development and manufacturing. In efforts to keep testing costs down, the use of older, less sophisticated testers is favored whenever practical. For example, a low cost test platform, very low cost tester (VLCT), is manufactured and used by Texas Instruments Corporation. The expense of the VLCT, is significantly less than more elaborate testers. However, VLCTs are more limited in terms of throughput and test capabilities. For example, unlike higher cost alternatives, the VLCT is not capable of at-speed functional testing, and while capable of performing scan testing, scan-based structural testing is limited to eight chains at either 15 or 30 MHz. In general, digital testing has required the use of sophisticated and expensive test equipment with the result that costs of the manufacture of semiconductor devices can be significantly increased, in terms of both time and equipment, by the demands of digital testing.

Due to these and other problems, it would be useful and advantageous to provide increased testing functionality to low cost testing platforms familiar in the arts. It would be particularly desirable to provide inexpensive, adaptable, and reusable systems and methods for performing digital testing independent of or in conjunction with existing low cost testers.

### SUMMARY OF THE INVENTION

In general, the invention provides methods and systems for implementing a testing module for digital testing of semiconductor devices.

According to one aspect of the invention, systems for digital testing include pattern memory for storing test vectors, and a digital test engine for using the stored test vectors to test characteristics of a device under test (DUT).

According to an additional aspect of the invention, systems for digital testing include an interface for connecting with automatic test equipment (ATE) in order to add testing capabilities complementary to those of the ATE.

According to a further aspect of the invention, methods for digital testing of semiconductor devices include steps of positioning a DUT in a socket, storing test vectors in memory, and providing digital inputs to the DUT in order to determine the operability of the DUT.

According to still another aspect of the invention, testing modules of the invention may be included with a test socket.

According to a further aspect of the invention, preferred embodiments include testing modules deployed between a device interface board (DIB) and ATE.

Preferred embodiments of the invention are also disclosed in which testing modules according to the invention are positioned on a DIB.

The invention provides technical advantages including but not limited to reductions in cost due to enhancing the capabilities and extending the usefulness of low cost testers, savings of time due to the enhanced capabilities of the low cost testers, and a reduction of the demands on higher cost testers. These and other features, advantages, and benefits of the present invention can be understood by one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a block diagram of components and steps in an example of a preferred embodiment of systems and methods of the invention;

FIG. 2 is a block diagram showing another example of a preferred embodiment of systems and methods of the invention;

FIG. 3 is an illustration of a testing environment using an example of a preferred embodiment of the invention;

FIG. 4 is a depiction of systems and methods of an example of an alternative preferred embodiment of the invention;

FIG. 5 is a view of another example of a preferred embodiment of a system of the invention; and

FIG. 6 is a block diagram illustrating a further example of a preferred embodiment of systems and methods of the invention.

References in the detailed description correspond to the references in the figures unless otherwise noted. Descriptive and directional terms used in the written description such as first, second, top, bottom, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the methods and apparatus of the invention provide improved capabilities to low cost production testers known in the arts. The methods and systems of the invention may be used to provide high performance testing capabilities to enhance the usefulness of preexisting test equipment.

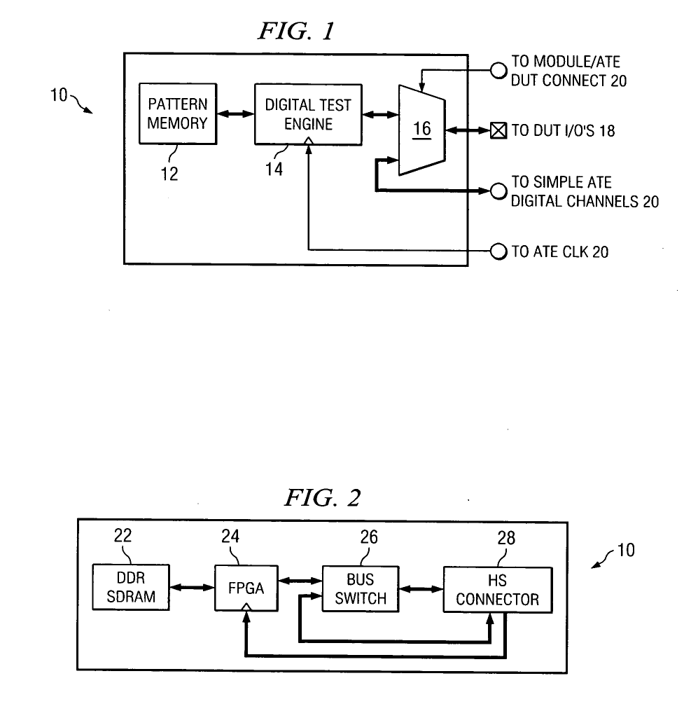

The block diagram of FIG. 1 shows an illustration of three functional components of systems and methods embodying the invention. A testing module 10 is shown. The term “testing module” as used herein contemplates hardware, software, firmware, or a combination thereof suitable for storing and implementing machine-readable instructions for carrying out the functions of the invention as further described. Pattern memory 12 stores the test vectors used for performing pre-selected tests. A digital test engine 14 sequences the patterned test vectors in order to provide the digital source, capture, and comparison required for each test or series of tests. This embodiment of the invention is illustrated with a bidirectional multiplexer 16, preferably used in order to provide an interface between a semiconductor device, generally referred to as a device under test (DUT) 18, and automatic test equipment (ATE) 20. It should be appreciated by those skilled in the arts that the module 10 of the invention may also be implemented in specific applications absent associated ATE 20. The preferred arrangement shown and described, including memory 12, test engine 14, and mux 16 for associating with ATE 20 provides a powerful test platform for performing scan testing, mixed signal testing, functional testing, and any combination of such testing selected for a particular application.

FIG. 2 shows a block diagram illustrating a preferred embodiment of a testing module 10 the invention using off-the-shelf components known in the arts. Those skilled in the arts will appreciate that this is but one example of a preferred embodiment of a testing module 10 of the invention. Numerous alternative embodiments providing the same functionality are possible without departure from the invention. The memory function is preferably implemented using DDR SRAM 22, preferably with a total capacity of 1 Gb or more and speeds of up to about 400 Mb per pin. Those skilled in the arts will appreciate that alternative memory devices may be used without departure from the invention provided that high speed and high density are provided. The test engine functionality is provided using a field programmable gate array (FPGA) 24. The use of an FPGA 24 as shown in this exemplary embodiment of the invention is preferred because it provides flexibility by allowing reprogramming. Thus, as test needs change, the firmware may be modified to provide new testing features. Current generations of readily available FPGAs have the capacity to perform operations at hundreds of MHz, have plentiful internal SRAM, support various I/O standards and have built-in clock management. This clock management may be used to form timing control for simple and fast functionality testing. A bus switch 26 may be used to perform the role of multiplexing. Solid-state based switches are preferred in order to avoid the problems associated with large, and relatively slow, mechanical relays. In the presently most preferred embodiment of the invention, the CBT family of devices available from Texas Instruments Corporation use a single series pass transistor as the switch, allowing bidirectional use over a large range of input/output voltages. Other solid-state switching mechanisms may be used without departure form the principles of the invention. To prevent the bus switch electrostatic discharge (ESD) structure (not shown) from masking continuity and leakage measurements, the Vss pin is preferably lowered to −1V. Since Vss is only used for the gate control of the series pass transistors, this does not affect operation as long as Vdd-Vss is within specified limits. A high speed connection 28 is provided in order to facilitate test input and output, and in typical applications, communication with automated test equipment 20.

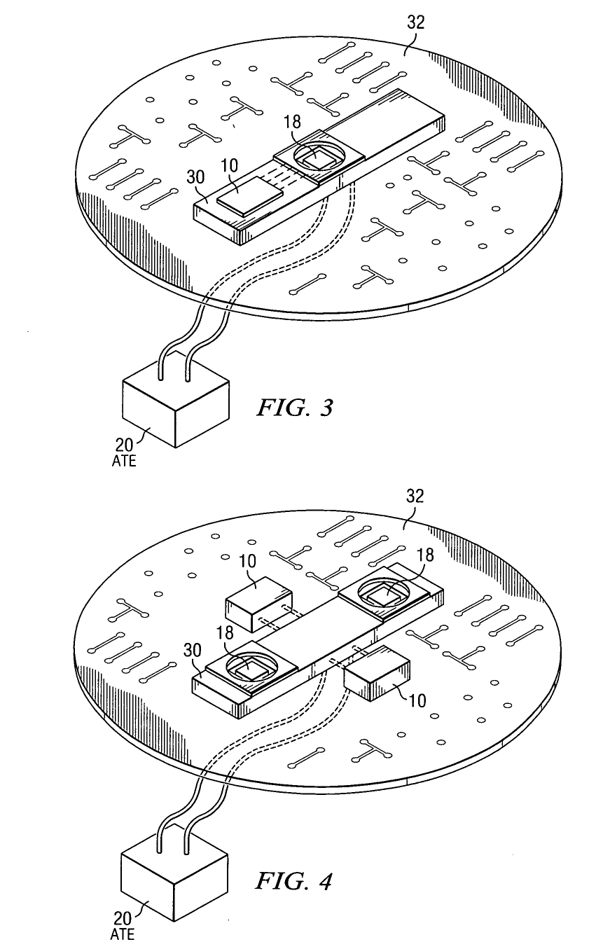

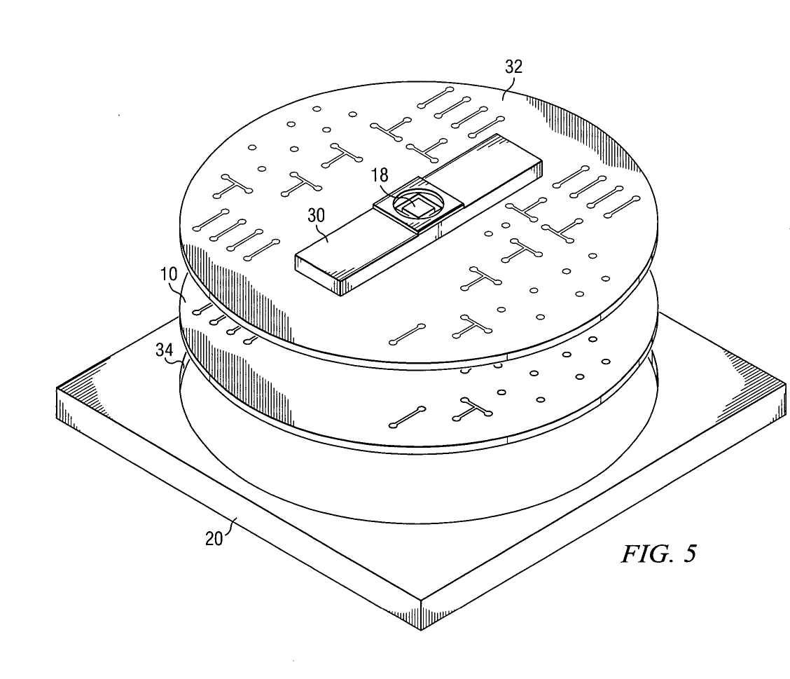

FIG. 3 shows a top perspective view of an exemplary embodiment of the invention implemented in a testing environment. A testing module 10 is shown operably connected to a test socket 30 on a device interface board (DIB) 32 familiar in the arts. A device under test (DUT) 18 is inserted in the socket 30 as is known in the testing arts. Automatic test equipment (ATE) 20 such as a VLCT is typically connected to the DUT 18 trough the socket 30 for testing selected inputs and outputs. The number of I/Os is generally limited by the memory configuration selected for the testing module 10. An appropriate memory configuration must be selected for the desired number of DUT I/Os that must be controlled, and the number of DUT sites. It should be appreciated by those skilled in the arts that in certain applications it may be desirable to perform various tests using the module 10 alone independent of the ATE 20, and that for other applications the module 10 and the ATE 20 may be used to perform simultaneous and/or complementary tests.

FIG. 4 shows an example of an alternative arrangement of test modules 10 with a dual-site DIB 32. Two at-speed digital test modules 10 are shown coupled to two test sockets 30. FIG. 3 illustrates an example of another alternative configuration embodying the invention. A typical socket 30, DIB 32, and DUT 18 arrangement as shown may be used with a testing module 10 configured for disposition between a DIB 32 and ATE 20 generally known in the arts. The module 10 is configured for making electrical contact at the interface 34 between the DIB 14 and ATE 18 by means of pogo pins, a probe membrane, or other suitable means. The examples of preferred embodiments of the invention shown and described are presented to illustrate and explain the principles and operation of the invention. It should be understood by those skilled in the arts that there are numerous possible alternative implementations of the principles of the invention. The examples shown and described are included to present features and advantages of various implementations of the invention and are not intended to be construed in a limiting sense.

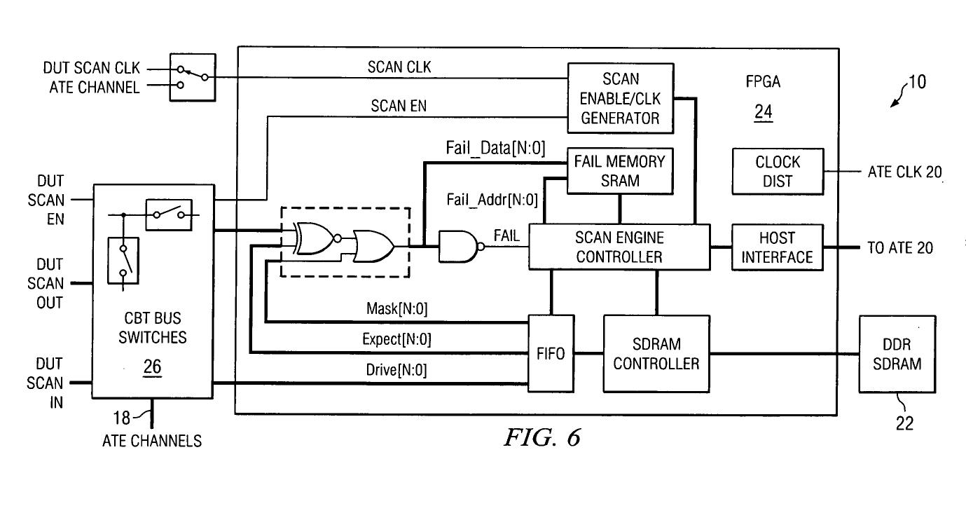

FIG. 6 shows a block diagram illustrating an example of a FPGA 24 firmware arrangement for scan testing. This example provides a block-level view of one possible implementation of the systems and methods of the invention. In the pattern memory 22, drive, expect and mask data is stored for each test vector. The controller is programmed to shift in the required data and compare the results that are shifted out after capture. If a failure occurs, it triggers the controller to log the result into fail memory and either stop the test or continue on fail, as pre-determined by the practitioner of the invention.

Thus, the invention provides systems and methods for digital testing of semiconductor devices using a testing module. While the invention has been described with reference to certain illustrative embodiments, the methods, systems, and apparatus described are not intended to be construed in a limiting sense. Various modifications and combinations of the illustrative embodiments as well as other advantages and embodiments of the invention will be apparent to persons skilled in the art upon reference to the description and claims.

1. For testing semiconductor devices, a digital testing system comprising:
pattern memory for storing test vectors adapted for performing digital tests;
a digital test engine for implementing test vectors of the pattern memory, whereby digital inputs are provided to a device under test (DUT) and digital DUT outputs are captured, thereby testing the operability of the DUT.

2. A digital testing system according to claim 1 further comprising:
a multiplexer for interfacing the DUT with automatic test equipment (ATE); and
ATE operably connected to perform testing on the DUT.

3. A digital testing system according to claim 1 wherein the digital testing system further comprises a testing module.

4. A digital testing system according to claim 1 configured to perform mixed signal testing.

5. A digital testing system according to claim 1 configured to perform scan testing.

6. A digital testing system according to claim 1 configured to perform functionality testing.

7. A digital testing system according to claim 3 wherein the testing module comprises a hardware device.

8. A digital testing system according to claim 3 wherein the testing module comprises firmware.

9. A digital testing system for adding digital test capability to an automatic test equipment (ATE) platform, the system comprising;
automatic test equipment (ATE) adapted for performing analog testing of a device under test (DUT); and
a testing module further comprising pattern memory, a test engine, and a multiplexer, for performing digital testing on the DUT.

10. A digital testing system according to claim 9 wherein the testing module further comprises DDR SRAM.

11. A digital testing system according to claim 9 wherein the testing module further comprises an FPGA.

12. A digital testing system according to claim 9 wherein the testing module further comprises a high speed bus.

13. A digital testing system according to claim 9 configured to perform scan mixed signal device testing.

14. A digital testing system according to claim 9 configured to perform scan testing.

15. A digital testing system according to claim 9 configured to perform functionality testing.

16. A method for digital testing of a semiconductor device under test (DUT) positioned in a socket on a device interface board (DIB), the method comprising the steps of:
storing test vectors for performing tests in machine-readable memory;
using the test vectors, providing digital inputs to the DUT and capturing and comparing digital DUT outputs, thereby determining the operability of the DUT.

17. A method according to claim 16 further comprising the step of interfacing the DUT with automatic test equipment (ATE).

18. A method according to claim 16 further comprising the step of using automatic test equipment (ATE) for testing analog properties of the DUT.

19. A method according to claim 16 wherein determining the operability of the DUT further comprises the step of scan testing.

20. A method according to claim 16 wherein determining the operability of the DUT further comprises the step of functionality testing.

21. A method according to claim 16 wherein determining the operability of the DUT further comprises the step of mixed signal testing.
